(19) United States
(12) Patent Application Publication
(10) Pub. No.: US 2008/0015800 A1
(43) Pub. Date: Jan. 17, 2008

(54) METHOD AND SYSTEM FOR DETERMINING FREQUENCY

(75) Inventor: Josef Hoelzle, Bad Woerishofen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/767,046

(22) Filed: Jun. 22, 2007

(30) Foreign Application Priority Data
Jun. 22, 2006 (DE) 10 2006 028 655.3

(51) Int. Cl. G01R 23/00; G06F 19/00

(52) U.S. Cl. 702/75; 702/1; 702/57; 702/66; 702/79

(57) ABSTRACT

A system and a method for determining frequencies is disclosed. In one embodiment, the system includes a delay device to generate a delayed second signal from a first signal. A logic device generates a third signal from the first signal and the second signal. A device filters a DC component from the third signal. A device determines the frequency of the first signal based on the DC component.

### CROSS-REFERENCE TO RELATED APPLICATIONS

This Utility Patent Application claims priority to German Patent Application No. DE 10 2006 028 655.3 filed on Jun. 22, 2006, which is incorporated herein by reference.

### BACKGROUND

The present invention relates to the field of frequency determination.

### SUMMARY

Various circuits are known for measuring and determining the frequency of one or more signals. Frequency measuring circuits are used in many different systems, devices, and integrated circuits.

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a frequency measuring apparatus based on one embodiment.

FIG. 2 illustrates a frequency measuring apparatus based on one embodiment.

FIG. 3 illustrates one embodiment of the combinational logic device.

FIG. 4 illustrates a flowchart for the method according to one embodiment.

FIG. 5 illustrates one embodiment.

FIG. 6 illustrates a schematic illustration of the counting range based on one embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

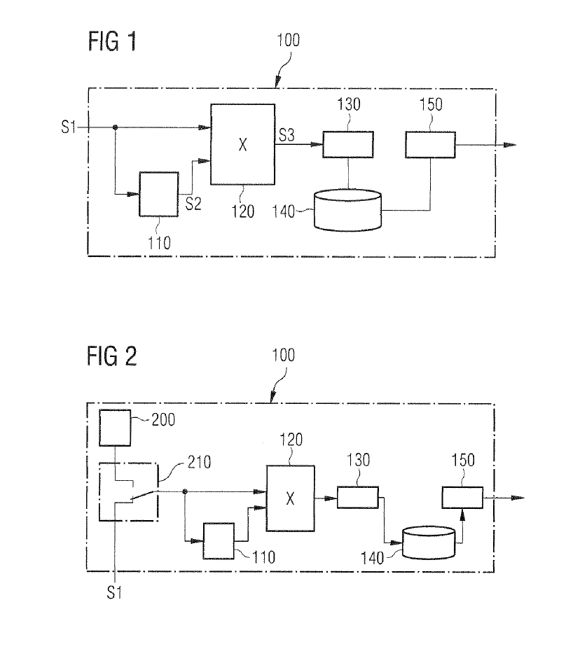

FIG. 1 illustrates a frequency measuring apparatus based on one embodiment.

The frequency measuring apparatus has an input S1 (not illustrated) which receives a signal which is to be measured. The data input is coupled to an input of the combinational logic device 120 and to an input of the delay device 110. In addition, an output of the delay device 110 is coupled to a second input of the combinational logic device 120. An output of the combinational logic device 120 is coupled to an input of the filter device 130. An output of the filter device 130 is coupled to an input of a memory device 140. In line with this embodiment, an output of the memory device 140 is coupled to the determining or ascertaining device for the purpose of ascertaining or determining the frequency value 150. An output of the ascertainment device 150 is coupled to a signal output in order to allow the ascertained frequency value to be output.

During operation, the data input is supplied with the signal S1, which is first of all forwarded to the delay device. The delay device prompts the signal to be delayed by a particular time. This phase-shifted signal or time-delayed signal is connected to the second input, in line with one embodiment, of the combinational logic device 120. The first input of the combinational logic device 120 receives the uncorrupted input signal S1. The corresponding input signals at the input of the combinational logic device 120 are multiplied or logically combined. The multiplication produces or generates a third signal S3, which has a DC voltage component value or an offset component and a frequency-dependent component.

The offset component of the third signal S3 is dependent on the frequency of the input signal S1. The frequency-dependent signal component of the third signal S3 is filtered out using the filter device 130. The filter device 130 may correspond to a low-pass filter or else it is possible to use another circuit with a corresponding mode of operation. The low-pass filter 130 is set up such that the harmonics of the third signal S3 are removed. The signal which now results corresponds to a mean value of the third signal S3. This mean value is the offset component of the third signal S3. That is to say that the output signal for the low-pass filter 130 is directly related to the frequency of the input signal S1. The low-pass filter 130 needs to be proportioned such that the output signal from the low-pass filter corresponds exactly to the offset component or DC voltage component of the third signal S3. The low-pass filter used may be a simple RC filter with a time constant of greater than or equal to ten times the period duration of the frequency to be measured, for example.

In line with one embodiment, the offset value of the third signal can be stored in a memory device 140 during the calibration. Storage in the memory device 140 allows later access to the value which has already been filtered.

The ascertainment device 150 can obtain the DC voltage value directly from the filter device 130, or the ascertainment device 150 accesses the memory device 140. The frequency of the input signal S1 is determined inside the ascertainment device 150. In line with one embodiment, the ascertainment device can access already stored values of the DC voltage component. These stored values may be inside the memory device 140. These already stored DC voltage component values can be allocated to nominal frequencies. That is to say that the ascertainment device can use known offset components or DC voltage components to decide upon a frequency range which contains the frequency of the current input signal S1.

It is conceivable that the frequency measuring apparatus in line with one embodiment can be integrated within an integrated circuit, for example, or else may be in the form of an external frequency measuring apparatus. One advantage of an integrated embodiment of the frequency measuring apparatus would be that the circuit to be tested or the signal to be tested can be coupled actually within the integrated circuit and the ascertained frequency can be forwarded as a DC voltage directly to test pins or to other dedicated connections. Direct measurement of a high-frequency signal can therefore be avoided and the measurement is transformed into a simple DC voltage measurement or a measurement of the DC voltage component.

FIG. 2 illustrates another embodiment of the frequency measuring or determining apparatus. The frequency measuring apparatus 100 which is illustrated in FIG. 2 differs from the frequency measuring apparatus 100 which is illustrated in FIG. 1 in that it contains an apparatus for generating nominal signals 200 and a switching apparatus 210 for connecting the apparatus 200. The switching device 210 is set up such that it can switch to and fro between a calibration mode and a nominal mode. The calibration mode means that the frequency measuring device is operated using nominal signals. That is to say that the circuit operates either in measurement mode or in calibration mode. In measurement mode, an unknown frequency can be applied, whereas in calibration mode, one or in the case of the lookup table a plurality of reference frequencies can be connected.

The nominal signals have reference frequencies and it is therefore possible to allocate a particular DC voltage component value to a known or reference frequency.

In “calibration mode”, a reference frequency of 500 MHz can be applied, for example, and accordingly an offset value or DC voltage component value of 500 mV can be measured. That is to say that the frequency of 500 MHz corresponds to an offset value of 500 mV. In normal mode, the signal S1 is connected again using the switching device 210. If the input signal S1 is likewise intended to have a frequency of 500 MHz, this corresponds to the fact that the now measured offset value is likewise intended to have 500 mV. If the offset value measured in normal mode does not correspond to 500 mV, it is possible to make the statement that the input signal does not have the required 500 MHz. The variation in the offset value can now be used to decide whether the frequency of the signal is higher than the reference frequency or lower. By connecting a plurality of reference signals in calibration mode, it is possible to achieve arbitrarily fine adjustment of the frequency measuring apparatus 100.

This turns complicated frequency measurement into simple measurement of a voltage value. The ascertained DC voltage value can be used to determine the frequency of the input signal.

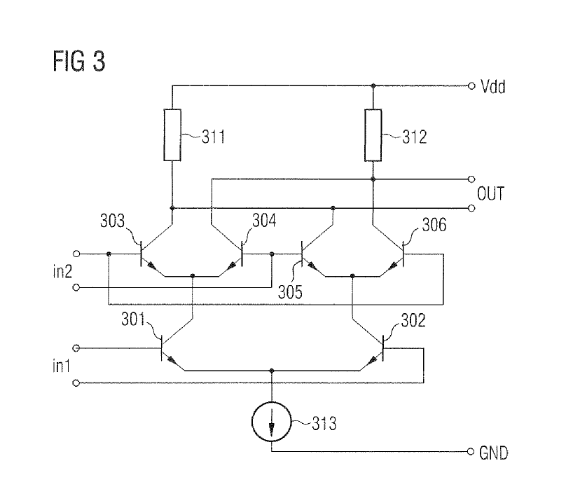

FIG. 3 illustrates an embodiment of the combinational logic device based on the present invention. The combinational logic device may be in the form of a Gilbert cell for example. The Gilbert cell or combinational logic device has two inputs IN2 and IN1 and an output OUT. In line with this embodiment the output signal OUT corresponds to the multiplication signal for the two input signals IN2 and IN1. The input signals for the combinational logic device from FIG. 3 may correspond to the signals S1 and S2, which are illustrated in FIG. 1. The Gilbert cell from FIG. 3 therefore multiplies the input signal S1 by the time-delayed signal S2. The output signal from the Gilbert cell OUT corresponds to the output signal S3 from FIG. 1. It is conceivable that, combinational logic devices other than a Gilbert cell may also be used which perform the same task. The main purpose of the combinational logic device is to logically combine two input signals IN2, IN1 to generate an output signal OUT. In this case, the Gilbert cell performs the task of a multiplier or a mixer.

In line with this embodiment, the Gilbert cell from FIG. 3 may be implemented in bipolar technology. In addition to the bipolar transistors, the Gilbert cell contains two resistors 311, 312 and a current source 313.

In principle the Gilbert cell from FIG. 3 includes three differential amplifiers. The first differential amplifier is formed from the bipolar transistors 303 and 304. The second differential amplifier includes the transistors 305 and 306, which are connected in similar fashion to the transistors 303 and 304. The currents which are required in order to operate the first and the second differential amplifiers are supplied by a third differential amplifier. The third differential amplifier, connected in similar fashion to the first two differential amplifiers, is formed from the transistors 301 and 302. As FIG. 3 reveals, the voltage IN1 or input voltage IN1 is connected between the respective base inputs of the transistors 301 and 302. Similarly, the second input voltage IN2 is connected between the base inputs of the transistor 303 and 304. In addition, one pole of the input voltage IN2 is connected to the base of the bipolar transistor 305.

The text below describes operation of the Gilbert cell based on the embodiment in FIG. 3.

If the input voltage IN1 is 0, the currents through the transistors 301 and 302 adopt a value which respectively corresponds to half the current through current source 313. That is to say that the currents can at most assume the value of the current through the transistor 313. The symmetrical design of the circuit means that the currents which will become established through the resistors 311 and 312 are therefore equal. This means that the output voltage OUT which is tapped off as a voltage difference is always zero, regardless of the voltage which is connected to the second input IN2. The resistors 311 and 312 are also called load resistors.

In the converse case, if the second input voltage IN2 is zero, identical currents will respectively become established through the transistors 303 and 304 or 305 and 306. Since the load resistors 311 and 312 carry the sum of a respective one of these two currents, the currents through the resistors 311 and 312 are equal (see above) and an identical output voltage with the value zero will again become established. This value, which in this case is zero, will become established regardless of the first input voltage. In this case, the Gilbert cell outputs the expected value zero for multiplication by zero.

In the normal mode of the Gilbert cell, the respective inputs IN2 and IN1 have two voltages supplied to them which are not equal to zero. The input voltage applied to the input IN1 prompts the currents through the transistors 301 and 302 to be of different magnitude. Since the currents through the transistors 301 and 302 are respectively used as supply currents for the first two differential amplifiers, the output voltage is proportional to the difference between these respective currents. Accordingly, the output signal OUT is proportional to the product of the two input voltages IN1 and IN2.

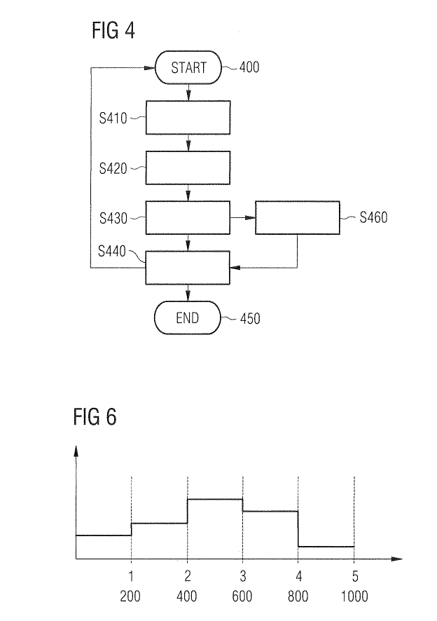

FIG. 4 is a flowchart for the method according to one embodiment. In a first process 400, a first signal is received. This signal may correspond to an oscillator signal or to a test signal, for example. The frequency of this test signal or oscillator signal therefore needs to be determined. In line with the method, the first signal is delayed by a predetermined delay time. This delay can be generated using a delay element or delay, for example. If the first signal is a harmonic signal, it can be represented in its general form as sin ωt. Following the delay, the delayed signal is represented in mathematical form
sin ω(t±Δt)
where Δt corresponds to the delay time which can be set using the delay element, and ω=2πf, where f corresponds to the frequency of the input signal.

In a subsequent process S420, the first signal is logically combined with a delayed signal. The delayed signal and the input signal are represented above in accordance with their mathematical formulae. In line with one embodiment of the present form the two signals are multiplied together.

$$sin ωt \cdot sin ω ( t - Δ t ) = \frac{1}{2} ⌊ \underbrace{cos ω Δ t} - \underbrace{cos ( 2 ω t - ω Δ t )} ⌋$$

where the first term corresponds to the DC offset or DC voltage component, and the second term corresponds to the high-frequency component, which is subsequently filtered out.

Hence, if the frequency f remains constant, the DC offset does not change. The offset is therefore a measure of the frequency. Accordingly, indirect frequency measurement can be performed using the DC offset.

This multiplication process S420 can be performed using a Gilbert cell or another multiplier.

The signal which results from the multiplication has a DC voltage component value and a high-frequency component. This high-frequency component is of no significance to the progression of the method. In a subsequent process S430, the resulting or logically combined signal is filtered in order to determine the DC voltage component value or the offset values.

In a process S460, the DC voltage component value which has now been ascertained can be stored in a memory device or lookup table. The lookup table can be used for effectively searching for a particular DC voltage component value. Alternatively, in a process S440, the frequency of the first signal can be ascertained on the basis of the DC voltage component value. When the frequency value has been ascertained, the method can be ended in a process S450. It is also conceivable for the method to be able to be restarted iteratively by applying a different input signal. In addition, the first signal may be a nominal signal. That is to say that the frequency of this signal is known. It is thus possible to derive a direct relationship between the frequency and the DC voltage component value which becomes established.

In addition, the method may contain a process of outputting the ascertained frequency.

The method can also be used to determine the delay times or delays for delay elements. These delay elements are required, by way of example, in order to achieve phase shift for signals. By supplying a signal at the standard frequency, it is possible to determine the delay time on the basis of the formula above.

The value obtained for the calibration at a standard frequency is used to fix the value Δt based on the formula illustrated above. Using the above formula, it is then possible to determine the frequency from the measured value and the known Δt. That is to say that it is necessary to store just one value.

In addition, one embodiment can be used to implement an f/U (frequency/voltage) converter. As mentioned above, there is a linear relationship between the frequency and the phase shift based on the factor ω*ΔT. Thus, the DC offset changes on the basis of the factor cos(ω*ΔT). Based on the frequency value, a frequency swing of Δf=1/ΔT generates the same DC offset values. By way of example, at 200 MHz and a delay of 5 ns, the phase shift is 360 degrees, at 400 MHz it is 720 degrees, at 600 MHz it is 1080 degrees etc. The expression for the effective phase shift is: f mod (200 MHz)*360 degrees, where mod corresponds to the modulo operator. Hence, there is a repetition in the DC voltage of the value cos (effective phase shift) at a frequency swing of Δf=200 MHz.

In line with one embodiment, it is possible to implement an extension of a measurement range for a measuring apparatus. This is achieved by counting the zero crossings in the DC offset signal. In line with one embodiment, the profile of the DC offset can be used as a clock signal for a digital counter. If the digital counter has the value 3, for example, this corresponds to a DC offset value of 60 degrees. Hence, the signal to be measured has a frequency corresponding to (3+60/360)*200 MHz=633 MHz using the underlying values. An infinite measurement range can therefore be implemented.

In the case of the f/U converter, the digital counter can be used to read a lookup table, a memory device, or to actuate another combinatorial circuit. The values generated in this manner can be interpreted as the gain by which the original input signal is altered. The adjustable delay element AT can be used to generate any desired profile of the f/U curve by using stages.

FIG. 5 illustrates one embodiment illustrating a circuit for frequency and phase measurement. The apparatus from FIG. 5 receives three signals at its input: an original signal 500, a phase-shifted original signal 503 and a selection signal 501. The selection signal 501 and the phase-shifted original signal 503 are supplied to a multiplexer 520. In addition, the multiplexer 520 receives a time-delayed original signal 505. The selection signal 501 can be used to set two modes of operation for the apparatus, frequency measurement and phase measurement. The output signal from the multiplexer 520 is forwarded to a multiplier 120 together with the original signal 500. The mode of operation and the action of the multiplier 120 are explained in more detail above. The output signal from the multiplier 120 is supplied to a filter device 130 which filters out the DC offset.

The filtered signal is supplied firstly to an analogue evaluation unit 510 and to a digital counter 580. The counter reading, which corresponds to the output of the digital counter 580, is forwarded to a device for determining the frequency 550. The device 550 likewise receives the output signal from the analogue evaluation unit 550. The device for determining the frequency 550 may include a lookup table 140. The table 140 can be used to determine a setting value which is used as a manipulated variable for the downstream amplifier 560. The output signal 590 corresponds to the output signal 590 from the amplifier 560.

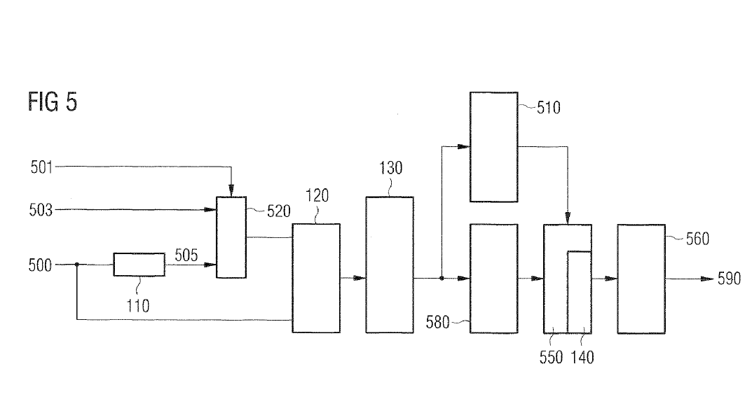

FIG. 6 illustrates the amplification of the amplifier 560 which is set on the basis of the counter reading. The x-axis illustrates the corresponding counter reading and the associated frequency in MHz (bottom row of Figures).

The implementation of the invention is not limited to the preferred exemplary embodiments indicated above. Rather, a number of variants are conceivable which make use of the inventive method in other manners of embodiments too. For example, one or more embodiments of this invention may be implemented in many systems, devices, and integrated circuits.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A system, comprising:
a delay device to generate a time-delayed second signal on the basis of a first signal;
a combinational logic device to logically combine the first signal with the second signal to generate a third signal;
a device to filter a DC voltage component of the third signal; and
a device to determine the frequency of the first signal on the basis of the DC voltage component.

2. The system of claim 1, comprising:
a memory device to storing at least one value for the DC voltage component.

3. The system of claim 2, wherein the memory device is a lookup table which is configured to store at least one DC voltage component value.

4. The system of claim 1, also comprising a generator device for generating nominal signals, where the nominal signals have reference frequencies.

5. The system of claim 1 and 4, comprising a switching device to connect the nominal signals configured to set up a calibration mode for the system.

6. The system of claim 1, wherein a delay time for the delay device is adjustable.

7. The system of claim 1, wherein the multiplication device/combinational logic device is a mixer.

8. The system of claim 1, where the multiplication device/combinational logic device is a multiplication device.

9. The system of claim 1, where the combinational logic device is a Gilbert cell.

10. The system of claim 1, comprising a digital counter, configured to receive the DC voltage component values.

11. A method for determining a frequency of a first signal, comprising:
receiving the first signal;
delaying the first signal by a predetermined delay time;
logically combining the first signal with the delayed signal, and to generate a logically combined signal;
filtering the logically combined signal to determine a DC voltage component value for the logically combined signal; and
determining the frequency of the first signal on the basis of the DC voltage component value.

12. The method of claim 11, comprising where the process of logic combination is multiplication of at least two signals.

13. The method of claim 11, also comprising:
storing the filtered DC voltage component value.

14. The method of claim 11, comprising:
generating a nominal signal, wherein the nominal signal has a reference frequency;
using the nominal signal as a first signal to start a calibration mode; and
storing a filtered DC voltage component value for the nominal signal.

15. The method of claim 11, also comprising:
outputting the determined frequency.

16. The method of claims 11, comprising:
comparing the filtered DC voltage value with the stored nominal DC voltage component value.

17. An apparatus, comprising:
means for receiving a first signal;
means for delaying the first signal by a predetermined delay time;
means for logically combining the first signal with the delayed signal, generating a logically combined signal;
means for filtering the logically combined signal to determine a DC voltage component value for the logically combined signal; and
means for determining the frequency of the first signal on the basis of the DC voltage component value.

18. The apparatus of claim 17, comprising where the means for logic combination is a multiplier having at least two inputs.

19. The apparatus of claim 17, comprising:
means for storing the filtered DC voltage component value.

20. The apparatus of claim 17, comprising:
means for generating a nominal signal, wherein the nominal signal has a reference frequency;
means for using the nominal signal as a first signal to start a calibration mode; and
means for storing a filtered DC voltage component value for the nominal signal.

21. The apparatus of claim 17, comprising means for outputting the ascertained frequency.

22. The apparatus of claim 18, comprising:
means for comparing the filtered DC voltage value with the stored nominal DC voltage component value.

23. The system of claim 1, comprising wherein the system is a measuring system to determine the frequency of a signal.
